(19) United States
(12) Patent Application Publication
(10) Pub. No.: US 2025/0323640 A1
(43) Pub. Date: Oct. 16, 2025

(54) GATE DRIVER FAULT REPORTING

(71) Applicant: Infineon Technologies Austria AG, Villach (AT)

(72) Inventors: Yuqiang QIU, Qingdao (CN); Karl Egil NORLING, Villach (AT)

(21) Appl. No.: 19/091,923

(22) Filed: Mar. 27, 2025

(30) Foreign Application Priority Data
Apr. 10, 2024 (DE) 102024203281.6

(51) Int. Cl. H03K 17/082; H03K 17/30; H03K 17/687

(52) U.S. Cl. CPC H03K 17/0822; H03K 17/302; H03K 17/687

(57) ABSTRACT

A gate driver system includes a plurality of gate drivers, each gate driver having a fault output node switchable between a fault state indicating a detected fault by the respective gate driver and an operating state. Timing arrangements are provided for each of the gate drivers, with each timing arrangement configured to switch a common node to a first state, responsive to the fault output node of the respective gate driver being set to the fault state (e.g., responsive to a trigger event). Then, after a predetermined time period having elapsed from a trigger event, the common node is released from the first state. As the predetermined time period for each of the timing arrangements is different, the amount of time between the trigger event and the common node being released from the first state may be measured to identify which gate driver among gate drivers that reported a fault.

### CROSS-REFERENCE TO RELATED APPLICATION

This application claims priority to Germany Patent Application No. 102024203281.6 filed on Apr. 10, 2024, the content of which is incorporated by reference herein in its entirety.

### FIELD

This implementation relates to gate drivers, and in particular to systems and methods for identifying the gate driver that has reported a fault.

### BACKGROUND

Gate drivers are power amplifiers that accept a low-power input from a controller and produce a high-current drive input for a gate of a high-power transistor (e.g., an IGBT or power MOSFET). A motor drive system, for example, may comprise six gate drivers, each providing input to a respective gate of a high-power transistor. Often, gate drivers comprise a pin (e.g., a fault output node) for reporting a fault detected by the gate driver. This pin can report internal faults of the gate driver, and/or faults of the transistor that the gate driver controls.

Nevertheless, in order to reduce a number of I/O pins of a controller, the fault output node of each of the gate drivers are typically connected to a single I/O pin. Thus, once a fault is detected by any of the gate drivers, the single I/O pin will indicate the presence of the fault, but the identity of the gate driver reporting the fault is lost. In other words, with this connection method, it is difficult to distinguish which gate driver has reported the fault, especially when the fault is triggered by random noise.

The inventors have thus identified a need for identifying the gate driver that has reported the fault whilst minimizing the required number of I/O pins.

### SUMMARY

According to one aspect of the implementation, there is provided a gate drive system. The gate drive system includes a plurality of gate drivers, each gate driver having a fault output node switchable between a fault state indicating a detected fault by the respective gate driver and an operating state. The system further includes a common node that is switchable between a first state and a second state; a timing arrangement for each of the gate drivers, each timing arrangement connected to the fault output node of the respective gate driver and the common node, each timing arrangement configured to set the common node to the first state responsive to the fault output node of the respective gate driver being set to the fault state; and release the common node from the first state responsive to a predetermined time period having elapsed from a trigger event, wherein the predetermined time period of each timing arrangement is different.

Concepts are provided for identifying the gate driver of a gate driver system that has reported a fault (e.g., to identify which gate driver among a plurality of gate drivers reported or is associated with the fault). The gate driver system includes a plurality of gate drivers, each gate driver having a fault output node switchable between a fault state indicating a detected fault by the respective gate driver and an operating state. Timing arrangements are provided for each of the gate drivers, with each timing arrangement configured to switch a common node to a first state responsive to the fault output node of the respective gate driver being set to the fault state. Then, after a predetermined time period having elapsed from a trigger event, the common node is released from the first state. As the predetermined time period for each of the timing arrangements (and thus each of the gate drivers) is different, the amount of time between the trigger event and the common node being released from the first state may be measured to identify the gate driver that reported a fault (e.g., the gate driver that switched the common node to the first state). Thus, the proposed concept enables the identification of the gate driver that reported the fault whilst using only a single output pin (e.g., connected to the common node).

In typical gate drivers, all of the fault output nodes (each corresponding to one gate driver) are connected to each other at one common node. This is to minimize the number of I/O pins required to report a fault. As a result, when a fault is detected by one gate driver (or a selection of gate drivers), the common node indicates that there is a fault detected by one (or more) of the gate drivers, but does not indicate which gate driver has reported the fault. Identifying the gate driver which has reported the fault may be useful for locating, and subsequently correcting, the cause of the fault.

Of course, alternatively each of the fault output nodes may be connected to a different I/O pin. Once a fault is detected by one of the gate drivers, then the corresponding I/O pin will indicate that there is a fault, and the location determined in a straightforward manner. However, this method requires a large number of I/O pins.

The disclosed implementation provides a solution to this issue without increasing the number of I/O pins to report the fault. Specifically, the disclosed implementation enables the identification of the gate driver that has reported the fault. This is achieved via a timing arrangement associated with each of the gate drivers, which initially sets the common node to the first state, and only releasing the common node from the first state after a predetermined period of time. Accordingly, an entity observing only the common node will initially be aware of the presence of a fault as the common node is set to the first state, and will be able to identify the gate driver that has reported the fault by monitoring the length of time between a trigger event and the common node being released from the first state.

That is, as the trigger event and the predetermined length of time associated with each gate driver (and provided by the timing arrangement) is known, then the common node can be monitored to identify the gate driver associated with the reported fault. Accordingly, the common node may be connected to a single I/O pin for reporting both the detection and location of the fault.

In some implementations, the first state may be a low state, and the second state may be a high state. That is, each timing arrangement may individually set the common node to a low state responsive to the fault output node of the respective gate driver being set to the fault state. Then, after a predetermined time period associated with the respective timing arrangement, the common node may be released from the low state (e.g., pulled/switched to the high state).

Accordingly, a falling edge of the common node may indicate that a fault output node of at least one of the gate drivers has been set to the fault state. Then, after a predetermined time period from a trigger event, a rising edge of the common node may indicate the gate driver having the fault output node that had been set to the fault state. In other words, the length of time between the trigger event and the rising edge on the common node will indicate which of the fault output nodes had been set to the fault state (and thus providing clues as to the location of the fault).

Nevertheless, in some implementations the first state may be a high state, and the second state may be a low state. Accordingly, a rising edge of the common node may indicate that a fault output node of at least one of the gate drivers has been set to the fault state. Then, after a predetermined time period from a trigger event, a falling edge of the common node may indicate the gate driver having the fault output node that had been set to the fault state. In other words, the length of time between the trigger event and the falling edge on the common node will indicate which of the fault output nodes had been set to the fault state (and thus providing clues as to the location of the fault).

The system may further include a controller connected to the common node. The controller may be configured to measure a length of time between the trigger event and the common node switching to the second state, and identify the gate driver corresponding to the detected fault based on the measured length of time and the predetermined time period of each respective timing arrangement.

The controller may therefore identify the gate driver having the fault output node that had been switched to the fault state by monitoring/measuring/determining a time between the trigger event and the common node switching to the second state. That is, the controller may consult a list of predetermined time periods and associated gate drivers, and match the time period elapsed from the trigger event and the common node switching to the second state to the list in order to ascertain the gate driver associated with the reported fault.

Of course, other means of providing the identity of the gate driver may be implemented in other implementations. For example, a sensor output may be provided to indicate the moment of the trigger event, followed by the moment the common node switches to the second state. A user may then be able to tell (from the amount of time from the two sensor outputs) which of the gate drivers has reported the fault.

The trigger event may be either the common node being set to the first state, or the fault output node of the respective gate driver being set to the operating state.

In other words, in some cases each of the timing arrangements are configured to delay an associated predetermined time period from when it sets the common node to the first state before releasing the common node from the first state. That is, the timing arrangement keeps the common node in the first state until the predetermined time period passes, at which point the common node is released from the first state.

In other cases, each of the timing arrangements are configured to delay an associated predetermined time period from when the fault output node of the associated gate driver is set to the operating state (from the fault state) before releasing the common node from the first state. Put another way, the timing arrangement waits a predetermined amount of time from a reset signal which resets each of the fault output nodes to the operating state.

When the trigger event is the common node being set to the first state, each timing arrangement may include a ramp generator and control logic. The ramp generator may be configured to generate a ramped output voltage responsive to the fault output node of the respective gate driver being set to the fault state. The control logic may be configured to set the common node to the first state responsive to the fault output node of the respective gate driver being set to a fault state and the ramped output voltage failing to meet a first voltage condition, and release the common node from the first state responsive to the ramped output voltage meeting the first voltage condition.

That is, the ramp generator outputs an increasing or decreasing voltage after the fault output node is set to the fault state. The control logic monitors the output voltage of the ramp generator, and compares the output voltage to a first voltage condition. Depending on the result of the comparison (e.g., whether the output voltage meets (satisfies) the first voltage condition or not), the common node is either set to the first state or released from the first state. The common node is released from the first state once the output voltage meets (satisfies) the first condition.

Accordingly, each timing arrangement is configured to set the common node to the first state, and release the common node from the first state after a predetermined time period from the trigger event (e.g., the common node being set to the first state). Either the rate at which the rate generator varies its associated output voltage, or the first voltage condition, may be set to ensure this operation according to the predetermined time period.

In some implementations, the ramp generator of each timing arrangement may be configured to generate the respective ramped output voltage such that the respective ramped output voltage meets the first voltage condition once the respective predetermined time period of the timing arrangement has elapsed from the trigger event. In this case, the first voltage condition of each timing arrangement may be the same.

In this case, the ramp generator of each timing arrangement is different in order to ensure that each timing arrangement has a different associated predetermined time period. Indeed, it will take each ramp generator a different amount of time for its associated output voltage to meet the first voltage condition.

Alternatively, the first voltage condition of each timing arrangement may be selected such that the ramped output voltage generated by the respective ramp generator meets the respective first voltage condition once the respective predetermined time period of the timing arrangement has elapsed from the trigger event.

In this case, the first voltage condition of each timing arrangement is different in order to ensure that each timing arrangement has a different associated predetermined time period. Indeed, if the ramp generator of each respective timing arrangement is the same, each ramp generator will require a different amount of time to meet the respective voltage condition of each timing arrangement.

The control logic of each timing arrangement may be further configured to set the common node to the first state responsive to the ramped output voltage meeting (satisfying) a second common voltage condition and the first voltage condition.

Accordingly, once the common voltage condition is met, the common node is re-set to the first state. This may be useful for continuing to indicate that a fault has been detected. That is, the common node will be set to the first state indicating a fault after being released for the purpose of indicating the identity of the gate driver reporting the fault.

In some cases, the ramp generator may include a capacitor, a current source, and a switch arranged to enable the current source to charge the capacitor responsive to the fault output node of the respective gate driver being set to the fault state.

This may provide a simple and cheap ramp generator for the purpose of the implementation. Nevertheless, other ramp generator arrangements are possible and would be readily appreciated by the skilled person.

The capacitance of the capacitor and/or an amperage of the current source of each ramp generator may be selected such that the respective ramped output voltage meets the first voltage condition once the respective predetermined time period of the timing arrangement has elapsed from the trigger event. In this case, the first voltage condition of each timing arrangement may be the same condition.

Indeed, the capacitor and/or current source of the ramp generator are parameters that may be altered to ensure that the output voltage meets the voltage condition after the respective predetermined time period.

When the trigger event is the fault output node of the respective gate driver being set to the operating state, each timing arrangement may include a ramp generator and control logic. The ramp generator may be configured to generate a ramped output voltage responsive to the fault output node of the respective gate driver being set to the operating state. The control logic may be configured to set the common node to the first state responsive to the fault output node of the respective gate driver being set to a fault state and the ramped output voltage failing to meet a voltage condition. The control logic may also be configured to release the common node from the first state responsive to the ramped output voltage meeting a voltage condition.

That is, the ramp generator outputs an increasing or decreasing voltage after the fault output node is set to the operating state (e.g., the fault output node is reset). The control logic sets the common node to the first state responsive to the fault output node being set to the fault state. The control logic then (once the fault output node is reset) monitors the output voltage of the ramp generator, and compares the output voltage to a voltage condition. The common node is released from the first state once the output voltage meets the first condition.

In some implementations, the ramp generator of each timing arrangement may be configured to generate the respective ramped output voltage such that the respective ramped output voltage meets the voltage condition once the respective predetermined time period of the timing arrangement has elapsed from the trigger event. In this case, the voltage condition of each timing arrangement may be the same.

Alternatively, the voltage condition of each timing arrangement may be selected such that the ramped output voltage generated by the respective ramp generator meets the respective voltage condition once the respective predetermined time period of the timing arrangement has elapsed from the trigger event.

The control logic of each timing arrangement may include a comparator configured to compare the ramped output voltage and a reference voltage (the reference voltage based on the voltage condition) to generate a comparison result, and set the common node to the first state or release the common node from the first state based on the comparison result.

In some implementations, the system may further include a biasing arrangement configured to bias the common node to the second state. Each timing arrangement may further include a switching arrangement connected to the common node, the switching arrangement of each respective timing arrangement configured to set the common node to the first state responsive to the fault output node of the respective gate driver being set to the fault state.

As a result of the biasing arrangement, the common node is switched to the second state once the common node is released from the first state. Meanwhile, the switching arrangement of each of the timing arrangements enables the timing arrangement to pull or switch the common node to the first state. Accordingly, when none of the switching arrangements pull the common node to the first state, the common node will be in the second state. When one or more of the timing arrangements, by the respective switching arrangements, switches the common node, the common node will be set to the first state until all timing arrangements allow the common node to be released.

In addition, there is provided a method for determining a location of a fault in a gate drive system including a plurality of gate drivers, each gate driver having a fault output node switchable between a fault state indicating a detected fault by the respective gate driver and an operating state. The method includes:
setting a common node to a first state responsive to the fault output node of one of the gate drivers being set to the fault state; and
releasing the common node from the first state responsive to a predetermined time period elapsing from a trigger event, the predetermined time period associated with the gate driver having the output node set to the fault state, and
wherein the predetermined time period associated with each gate driver is different.

### BRIEF DESCRIPTION OF THE DRAWINGS

The implementation will now be described by way of example with reference to the accompanying drawings, in which:

FIG. 1 is a circuit diagram showing a gate driver system according to a generalized prior art example;

FIG. 2 is a simplified block diagram of a gate driver system according to an implementation of the implementation;

FIG. 3 is a circuit diagram of a timing arrangement according to an implementation of the implementation;

FIG. 4 is a timing diagram of the circuit of FIG. 3;

FIG. 5 is a circuit diagram of a gate driver system incorporating the timing arrangement of FIG. 3;

FIG. 6 is a timing diagram of the general concept of the gate driver system of FIG. 5;

FIG. 7 is a timing diagram of the gate driver system according to an implementation of the implementation in a situation in which multiple gate drivers simultaneously report a fault;

FIG. 8 is a circuit diagram of a timing arrangement according to another implementation of the implementation;

FIG. 9 is a timing diagram of the circuit of FIG. 8;

FIG. 10 is a circuit diagram of a gate driver system incorporating the timing arrangement of FIG. 8;

FIG. 11 is a circuit diagram of a timing arrangement according to a further implementation of the implementation;

FIG. 12 is a timing diagram of the circuit of FIG. 11;

FIG. 13 is a circuit diagram of the timing arrangement of FIG. 11 having a first means of adjusting an associated predetermined time period;

FIG. 14 is a circuit diagram of the timing arrangement of FIG. 11 having a second means of adjusting an associated predetermined time period;

FIG. 15 is a circuit diagram of the timing arrangement of FIG. 11 having a third means of adjusting an associated predetermined time period;

FIG. 16 is a circuit diagram of the timing arrangement of FIG. 11 having a fourth means of adjusting an associated predetermined time period; and

FIG. 17 is a flow diagram of a method for determining a location of a fault in a gate drive system according to an implementation of the implementation.

It should be noted that these figures are diagrammatic and not drawn to scale. Relative dimensions and proportions of parts of these figures have been shown exaggerated or reduced in size, for the sake of clarity and convenience in the drawings.

### DETAILED DESCRIPTION

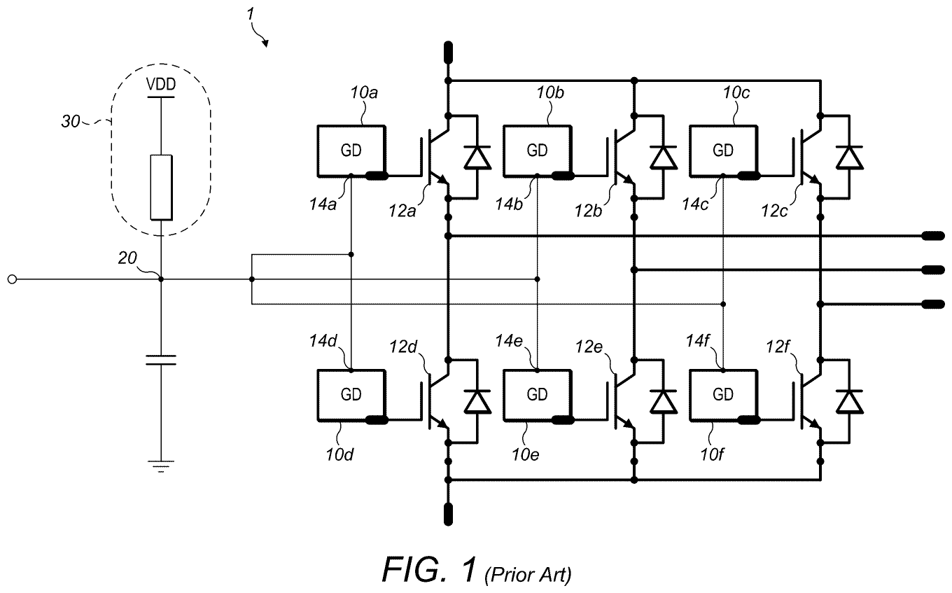

To understand the present disclosure, it is important to understand the operation of a typical gate driver system. FIG. 1 is a circuit diagram of a gate driver system 1.

As shown, each gate driver 10a-f provides input to a gate of a respective switch 12a-f (e.g., an IGBT, a GaN transistor, or a power MOSFET). Each gate driver 10a-f also provides the capacity for reporting that a fault has been detected. The fault may, for example, be an internal fault of the gate driver 10a-f, may correspond to the switch 12a-f or a component connected to the switch 12a-f. Specifically, each gate driver 10a-f reports the presence of a fault by a fault output node 14a-f. The fault output node 14a-f may be in an operating state (e.g., a high or clear state) indicating that no fault has been detected by the gate driver, or in a fault state (e.g., a low state) indicating that a fault has been detected by the respective gate driver.

Each of the fault output nodes 14a-f are typically connected together via one common node 20. As a result, if any one of the fault output nodes 14a-f is in a fault state, the common node 20 will report that there is a fault. Thus, the gate driver 10a-f that detected the fault will not be derivable from information on the common node 20.

Specifically, each of the gate drivers 10a-f are usually configured to individually pull the common node 20 to a low state (e.g., to ground) when they detect a fault. As the common node 20 is biased to a high state (e.g., VDD), by a biasing arrangement 30, if none of the gate drivers 10a-f detect a fault then the common node 20 will be in the high state. This binary system does not allow for the reporting of which of the gate drivers 10a-f has detected and reported a fault.

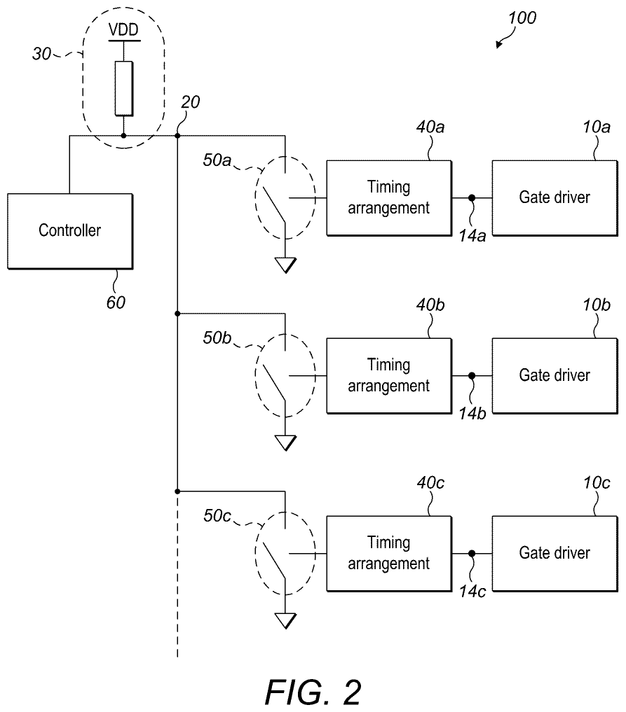

FIG. 2 presents a simplified block diagram of an implementation of the implementation. Specifically, FIG. 2 presents a gate driver system 100 that enables the identification, by one common output node 20, of the gate driver 10a-c that has reported a fault.

Similarly to FIG. 1, the gate drive system 100 comprises a plurality of gate drivers 10a-c. As described above, each gate driver 10a-c has a fault output node 14 switchable between a fault state and an operating state. There are three gate drivers 10a-c shown, but there may only be two gate drivers, or there may be more than three gate drivers.

In addition, there is provided a timing arrangement 40a-c for each of the gate drivers 10a-c. Each timing arrangement 40a-c is connected to the fault output node 14a-c of the respective gate driver 10a-c and a common node 20. That is, each gate driver 10a-c has a timing arrangement 40a-c connected between the fault output node 14a-c of the gate driver 10a-c and a common node 20. To be clear, all of the timing arrangements 40a-c are connected to the same common node 20.

Each timing arrangement 40a-c may be implemented separately from the gate driver 10a-c (e.g., connected to a pin of the gate driver 10a-c outputting a fault signal as the fault output node 14a-c). Alternatively, one or more components of the timing arrangement 40a-c may be implemented as part of the gate driver 10a-c, with the timing arrangement 40a-c connected to an internal fault node of the gate driver 10a-c as the fault output node 14a-c.

The common node 20 is switchable between a first state and a second state. In the depicted case, the common node 20 is biased toward a second state by a biasing arrangement 30, and may be switched/pulled to the first state by any of the timing arrangements 40a-c. The first state in the depicted implementation is a low state (e.g., a grounded state). The second state in the depicted implementation is a high state (e.g., VDD). However, modifications of the depicted implementation may be made such that the first state is a high state, and the second state is a low state.

In some implementations, the common node 20 may be connected to an I/O pin enabling a user to monitor, detect, and diagnose faults.

Each timing arrangement 40a-c is configured to set the common node 20 to the first state responsive to the fault output node 14a-c of the respective gate driver 10a-c being set to the fault state. In other words, when a gate driver 10a-c detects a fault, the fault output node 14a-c is set to a fault state. In turn, the timing arrangement 40a-c associated with the gate driver 10a-c will set the common node 20 to the first state. In the depicted example, this is achieved by closing a switching arrangement 50a-c so that the common node 20 is pulled to the first (e.g., low) state.

Furthermore, each timing arrangement 40a-c is configured to release the common node 20 from the first state responsive to a predetermined time period having elapsed from a trigger event. In the depicted example, this is achieved by opening the switching arrangement 50a-c so that the common node 20 may be pulled back to the second (e.g., high) state by the biasing arrangement 30. In other words, the timing arrangement 40a-c controls the switching arrangement 50a-c to remove the short circuit of the common node 20 to ground after a predetermined time period has elapsed from a trigger event.

In order to differentiate between the different gate drivers 10a-c, the predetermined time period of each timing arrangement 40a-c is different. That is, each of the timing arrangements 40a-c release the common node from the first state after a different length of time from a same trigger event.

To be clear, the predetermined time period of each timing arrangement 40a-c may be a specific length of time, or may be a time range that takes into account tolerances with external components. In any case, the predetermined time periods are different in that they may be differentiated from each other (e.g., if the predetermined time periods are time ranges, then these time ranges will not overlap).

For example, if a fault is detected by a first gate driver 10a, a first timing arrangement 40a may wait 1 second from a trigger event before releasing the common node 20. In the same system, if a fault is detected by a second gate driver 10b, a second timing arrangement 40b may wait 2 seconds from a trigger event before releasing the common node 20.

Accordingly, by monitoring the common node 20 and determining a time between a trigger event and the common node 20 being released from the first state, the gate driver 10a-c that detected the fault may be determined.

To this end, the gate drive system 100 may further comprise a controller 60 connected to the common node 20. The controller 60 is configured to measure a length of time between the trigger event and the common node 20 switching to the second state. The controller 20 then identifies the gate driver 10a-c corresponding to the detected fault based on the measured length of time and the predetermined time period of each respective timing arrangement 40a-c.

In some implementations of the implementation, the trigger event may be the common node 20 being set to the first state. In this case, upon the respective fault output node 14a-c being set to a fault state, the timing arrangement 40a-c sets the common node 20 to the first state, delays a predetermined period of time, and then releases the common node 20 from the first state. Of course, each timing arrangement 40a-c delays a different predetermined period of time, and therefore this delay may be monitored to determine the gate driver 10a-c reporting the fault.

In other implementations, the trigger event may be the fault output node 14a-c of the respective gate driver 10a-c being set to the operating state. In other words, the trigger event is when the fault output node 14a-c is reset/cleared after being in a fault state. Thus, the trigger event may equally be the generation of a reset signal. In this case, upon the fault output node 14a-c being set to the operating state, the timing arrangement 40a-c delays a predetermined period of time, and then releases the common node 20 from the first state. Of course, each timing arrangement 40a-c delays a different predetermined period of time, and therefore this delay may be monitored to determine the gate driver 10a-c reporting the fault.

Of course, implementations may have other trigger events that would be readily apparent to the skilled person. For example, the trigger event may be the occurrence of a user signal that begins the delay before the common node 20 is released from the first state.

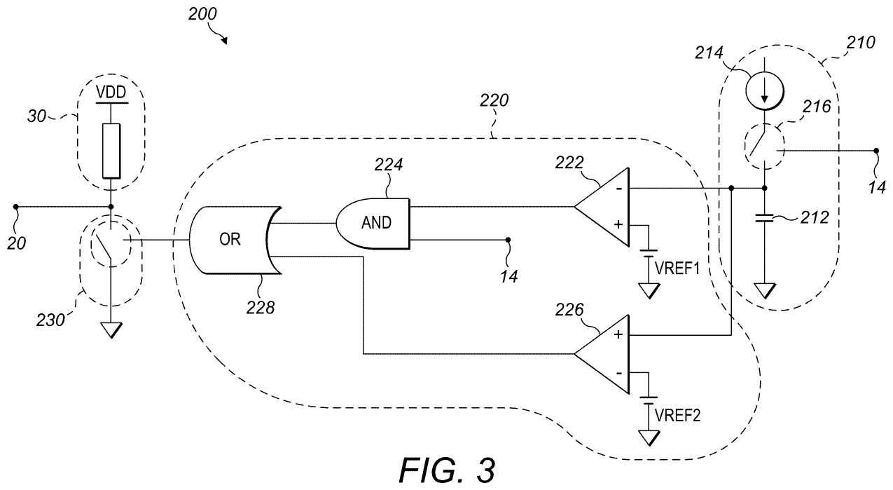

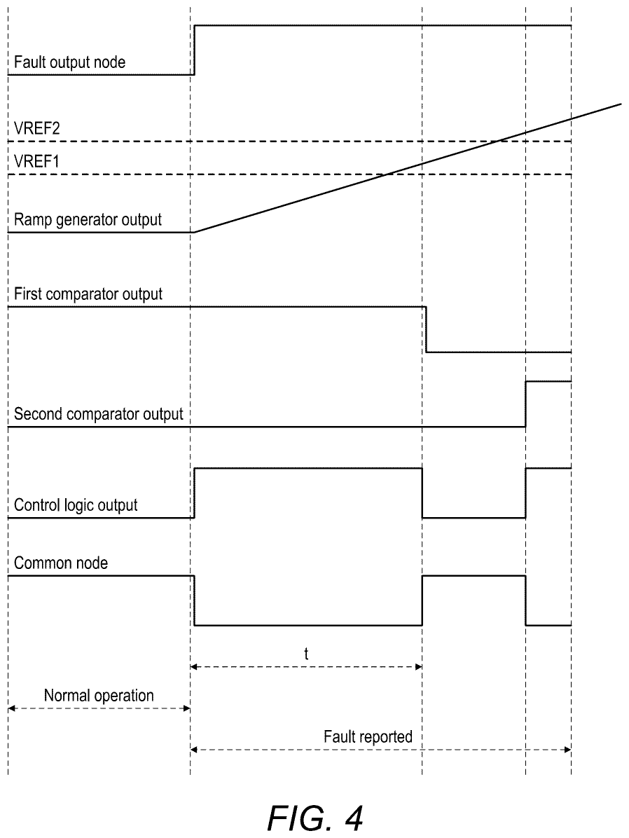

Turning to FIG. 3, there is presented a circuit diagram of an example implementation of a timing arrangement 200 for a gate driver 10a-c according to an aspect of the present implementation. The timing arrangement 200 of FIG. 3 acts according to the trigger event being the setting of the common node 20 to the first state. That is, the timing arrangement 200 of FIG. 3 first sets the common node 20 to the first state, delays for a predetermined time period, and then releases the common node 20 from the first state. The operation of the timing arrangement 200 of FIG. 3 is made also with reference to the timing diagram of FIG. 4.

The timing arrangement 200 may be implemented in the gate driver 10a-c. That is, the fault output node 14a-c of the gate driver 10a-c may be internal, and many of the components of the timing arrangement 200 of FIG. 3 may be provided in the respective gate driver 10a-c. Of course, each of these components may also be provided separately to the respective gate driver 10a-c, with the fault output node 14a-c being a fault output pin of the gate driver 10a-c.

As shown, the timing arrangement 200 is connected to the fault output pin 14 of a gate driver 10, and a common node 20. The timing arrangement 200 comprises a ramp generator 210, control logic 220, and a switching arrangement 230.

The ramp generator 210 is configured to generate a ramped output voltage responsive to the fault output node 14 of the respective gate driver 10 being set to the fault state.

Specifically, the ramp generator 210 comprises a capacitor 212, a current source 214, and a switch 216 arranged to enable the current source 214 to charge the capacitor 212 responsive to the fault output node 14 of the respective gate driver 10 being set to the fault state. Accordingly, when the fault output node 14 of the gate driver 10 is in the fault state, the switch 216 of the ramp generator 210 closes. The current source 214 begins to charge the capacitor 212, which leads to a rising output voltage. The rising output voltage is provided to the input of the control logic 220.

The current source 214 may be connected in series with the capacitor 212, or may be connected in parallel with the capacitor 212. Furthermore, the current source 214 may, in principle, also be implemented as a resistor connected to a voltage source.

The profile of the output voltage of the ramp generator 210 may be selected by appropriate selection of the capacitance of the capacitor 212 and/or the amperage of the current source 214.

Of course, the depicted ramp generator 210 is by way of example only, and other topologies of the ramp generator 210 are possible and would be readily implemented. For example, the ramp generator 210 may provide a decreasing voltage output. Equally, the output voltage of the ramp generator 210 may vary in a substantially linear manner, or may vary in non-linear manner. The ramp generator 210 simply needs to generate a monotonic and predictable varying voltage to provide to the input of the control logic 220.

The control logic 220 is configured to set the common node 20 to the first state responsive to the fault output node 14 of the gate driver 10 being set to a fault state and the ramped output voltage failing to meet a first voltage condition. Specifically, the control logic 220 closes a switch of the switching arrangement 230 so as to pull the common node 20 to a low/ground state responsive to the fault output node 14 being set to a fault state.

The control logic 220 is configured to then release the common node 20 from the first state responsive to the ramped output voltage meeting the first voltage condition. Specifically, the control logic 220 opens the switch of the switching arrangement 230 so as to release the common node 20 from the low/ground state responsive to the ramped output voltage meeting the first voltage condition.

In addition, the control logic 220 of the timing arrangement 200 may be further configured to set the common node 20 to the first state responsive to the ramped output voltage meeting a second common voltage condition and the first voltage condition. Specifically, the control logic 220 closes the switch of the switching arrangement 230 so as to set the common node 20 back to the low/ground state responsive to the ramped output voltage meeting the first and second voltage condition.

For example, the first voltage condition may be the output voltage of the ramp generator 210 being 2V, the second common voltage condition may be the output voltage of the ramp generator 210 being 2.5V. The ramp generator 210 may have a linearly increasing output voltage of 0.5V per second. As a result, (once the fault output node 14 of the respective gate driver 10 is set to a fault state) the common node 20 is set to the first state at 0s. At 4s, the common node 20 is released from the first state. At 5s, the common node 20 is set to the first state. Of course, these parameter values are meant by way of illustrative example only.

Generally, the time period, t, (e.g., the predetermined time period of the timing arrangement 200) between the common node 20 being set to the first state and being released from the first state may be formulated as:

$$t = \frac{C * V R E F 1}{I} \qquad [ 1 ]$$

where C is the capacitance of the capacitor 212, I is the amperage of the current source 214, and the first voltage condition is satisfied once the voltage across the capacitor 212 exceeds VREF1.

It can be seen from [1] that the first voltage condition and/or ramp generator output voltage 210 (e.g., the capacitance of the capacitor 212 and/or amperage of the current source 214) may be altered in order to set the predetermined time period of the timing arrangement 200. Accordingly, each timing arrangement 200 of a gate driver system may have one or more different voltage conditions and ramp generator output voltages to ensure that each timing arrangement 200 has a different predetermined time period.

FIG. 4 is a timing diagram of the timing arrangement 200 of FIG. 3.

During normal operation (e.g., when the gate driver 10 has not detected a fault), the fault output node 14 remains in a low (e.g., operating) state. As a result, there is no voltage across the capacitor 212. Following through the logic gates and comparators, the output of the control logic 220 means that the switch 230 is turned off and therefore the common node 20 remains in a released state (and therefore is in the second state due to a biasing arrangement 30). Specifically, the output of the AND gate 224 is low as the fault output node is low (despite the first comparator 222 being high), and the output from the second comparator 226 is low as there is no voltage across the capacitor 212. As a result the output from the OR gate 228 is low.

Once the fault output node 14 is set to a high (e.g., fault) state, the switch 216 is turned on and the common node 20 is pulled to the first state. This is because the fault output node 14 is in the high state, resulting in a high output from the AND gate 224 (with the first comparator 222 remaining in the high state), and a high output from the OR gate 228. At this time, the switch 216 of the ramp generator 210 is closed, so the current source 214 begins charging the capacitor 212, leading to an increasing voltage output from the ramp generator 210. The first comparator 222 remains in the high state as the voltage across the capacitor 212 remains below the first voltage threshold VREF1 (e.g., does not meet the first voltage condition). The second comparator 226 remains low as the voltage across the capacitor 212 remains below the second voltage threshold VREF2 (e.g., does not meet the second common voltage condition).

Then, once the voltage across the capacitor 212 exceeds the first voltage threshold VREF1 (e.g., meets the first voltage condition), the output of the first comparator 222 falls to low. Accordingly, the output from the AND gate 224 becomes low, and so does the output of the OR gate 228. The switch of the switching arrangement 230 therefore opens releasing the common node 20 from the first state. This should occur after the predetermined time period (t) having elapsed from the fault output node 14 being set to a high (e.g., fault) state. Again, the second comparator 226 remains low as the voltage across the capacitor 212 remains below the second voltage threshold VREF2 (e.g., does not meet the second common voltage condition).

Finally, the output of the second comparator 226 becomes high once the voltage across the capacitor 212 exceeds the second voltage threshold VREF2 (e.g., meets the second common voltage condition). Accordingly, the output from the OR gate 228 becomes high, once again pulling the common node 20 to the first, low, state.

The time, t, between the first falling edge of a signal present on the common node 20, and the first rising edge of the signal present on the common node 20 should therefore substantially match the predetermined time period.

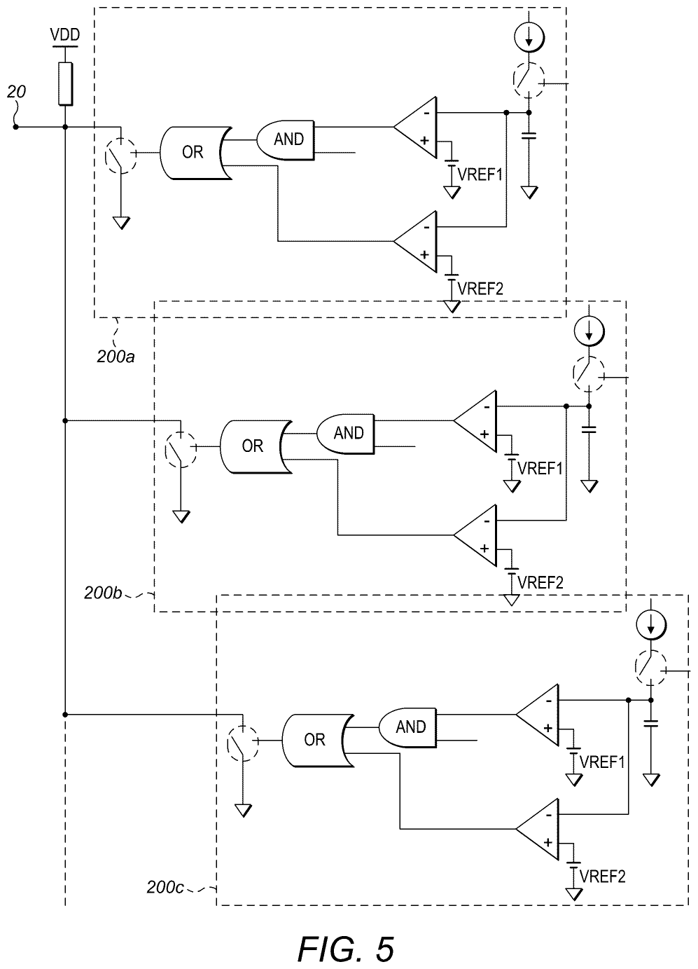

FIG. 5 depicts a circuit diagram of a gate drive system according to an implementation of the implementation comprising timing arrangements 200a-c as depicted in FIG. 3.

Each gate driver has an associated timing arrangement 200a-200c connected between the respective fault output pin and a common node 20. The common node 20 is biased to a high state (e.g., the second state) by the (shared) biasing arrangement. When any of the fault output pins are set to a fault state, the respective timing arrangement 200a-c will operate as described above.

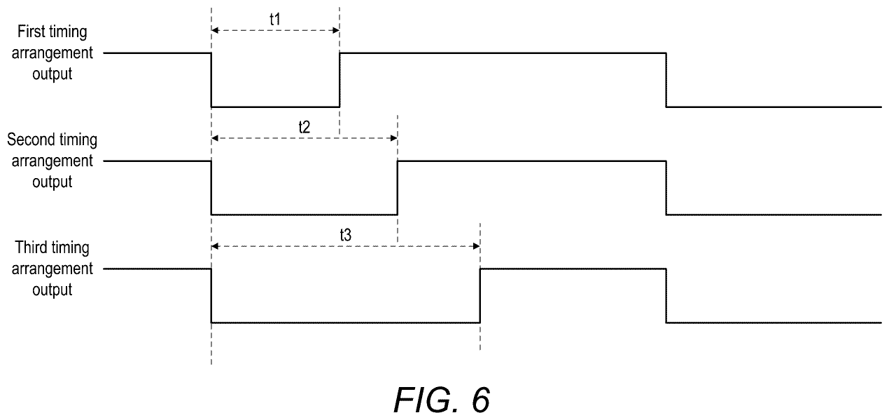

Of course, each timing arrangement 200a-c corresponds to a different predetermined time period by virtue of having different first voltage conditions, or ramp generator output voltage profiles as described above. This is presented by the timing diagram of FIG. 6, representing a signal on the common node 20 when either a first timing arrangement 200a, second timing arrangement 200b or third timing arrangement 200c is associated with a fault output node set to a fault state. As seen, there is a difference between the time at which the common node 20 is set to the low state and the time at which the common node 20 is released from the low state to the high state (represented as t1-3). By monitoring this time delay, the timing arrangement 200a-c responsible for this signal on the common node 20 (and thus the gate driver 10a-c reporting the fault) can be identified.

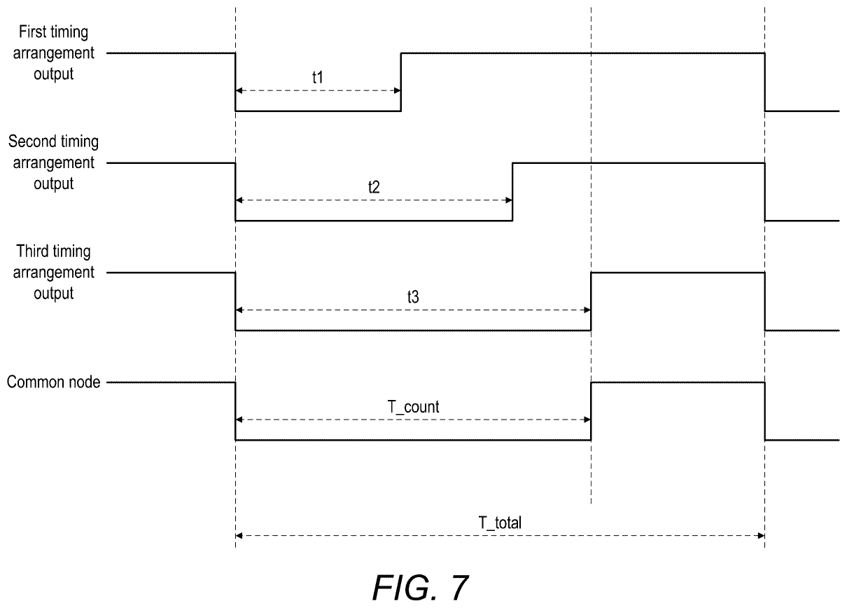

Supposing that more than one of the gate drivers detects a fault at the same time, the common node 20 will be switched/pulled to the first state by more than one of the timing arrangements 200a-c at the same time. This is shown in FIG. 7, where three timing arrangements 200a-c switch the common node 20 to the first state at the same time.

In this case, the timing arrangements 200a-b configured to have shorter predetermined time periods (e.g., t1 and t2) release the common node 20 from the first state. However, the common node 20 will remain in the first state, as the timing arrangement 200c with the longest predetermined time period (e.g., t3) will continue to pull the common node 20 to the first state. Thus, on the common node 20, only the gate driver with the longest predetermined time period will be able to be identified. This is seen in FIG. 7, as the common node 20 only returns to the second state once all of the timing arrangements 200a-c release the common node 20 from the first state.

Nevertheless, in practice this should not be an issue, as the faults will likely need to be resolved one-by-one. Accordingly, once the issue triggering the fault on the gate driver associated with the longest predetermined time period is resolved, the gate driver associated with the second longest predetermined time period will be identified.

Finally, as shown in FIG. 7, and according to the circuit diagram depicted in FIG. 6, the common node 20 will be pulled/switched back to the first state once the voltage output of the ramp generator satisfies the second common voltage condition.

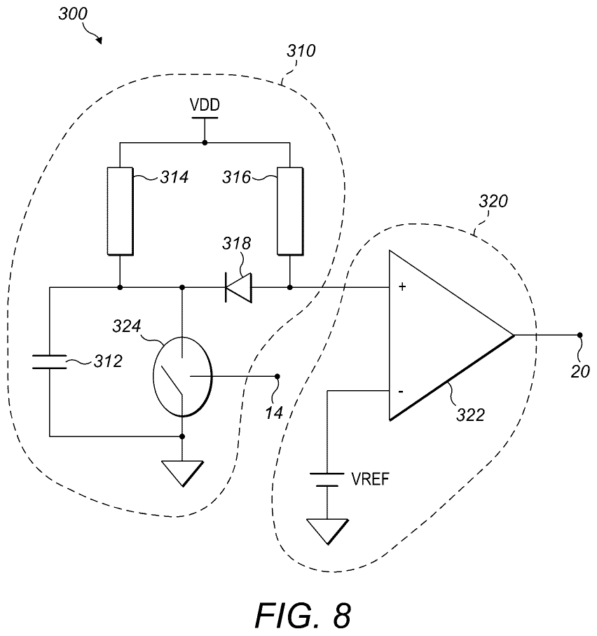

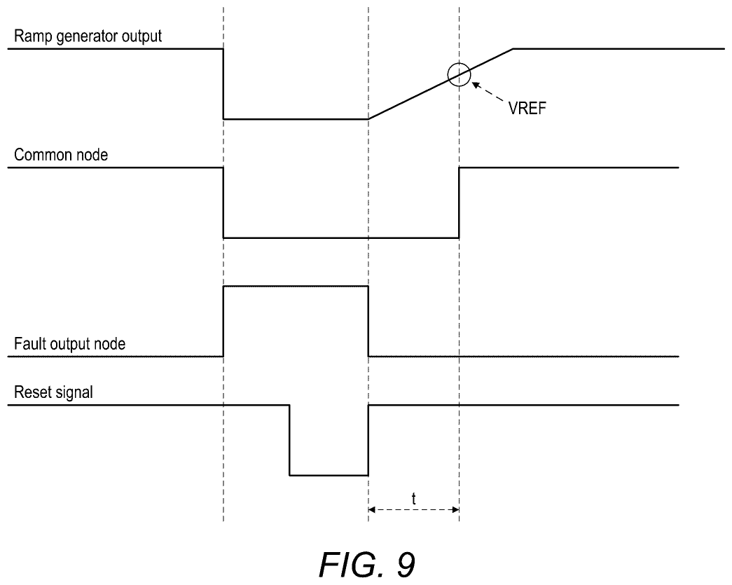

Moving onto FIG. 8, there is presented a circuit diagram of an example implementation of a timing arrangement 300 for a gate driver 10 according to another aspect of the present implementation. The timing arrangement 300 of FIG. 8 acts according to the trigger event being the setting of the fault output node 14 of the respective gate driver 10 to the operating state. That is, the timing arrangement 300 of FIG. 8 is configured to initially set the common node 20 to the first state, wait for a reset signal for resetting the fault output node 14 to the operating state, delays for a predetermined time period, and then releases the common node 20 from the first state. The operation of FIG. 8 is also explained with reference to the timing diagram of FIG. 9.

Typically, when a fault state of a fault output pin/node 14 of a gate driver 10 is cleared (to the operating state), a reset pin must be set to a (usually low) state for a defined time, before being released to another (usually high) state. Accordingly, the trigger event may be reworded as the reset pin being reset to a second state after being set to a first state for a defined time period. Of course, in practice this results in the fault output pin 14 of the gate driver 10 being set to the operating state (reset from the fault state), and therefore this may be considered the trigger event for the sake of simplicity. In other words, the time measured between the trigger event and the common node 20 being released to the second state (to identify the gate driver reporting the fault) is from a rising edge of a signal on a reset pin to a rising edge of a signal on the common node 20.

Alternatively, it may be the case that the trigger event and reset is when the reset pin is initially set to the low state, rather than from the point when the reset pin is released to the high state (e.g., the falling edge of the reset signal in FIG. 9). In other words, the trigger event is when there is a falling edge on the reset pin, resulting in the fault output node/pin 14 being set to the operating state. Therefore, the ramp generator 310 output may begin increasing from the time that the reset pin is initially pulled to the (usually low) state.

As shown, the timing arrangement 300 is connected to the fault output node 14 of a gate driver 10, and a common node 20. The timing arrangement 300 comprises a ramp generator 310, and control logic 320.

The ramp generator 310 is configured to generate a ramped output voltage responsive to the fault output node 14 of the respective gate driver 10 being set to the operating state.

Specifically, the ramp generator 310 comprises a capacitor 312 connected to ground, a first resistor 314 and a second resistor 316 connected in parallel and provided between a voltage source and the capacitor 312, and a diode 318 allowing current to flow through the second resistor 316 and capacitor 312 to ground.

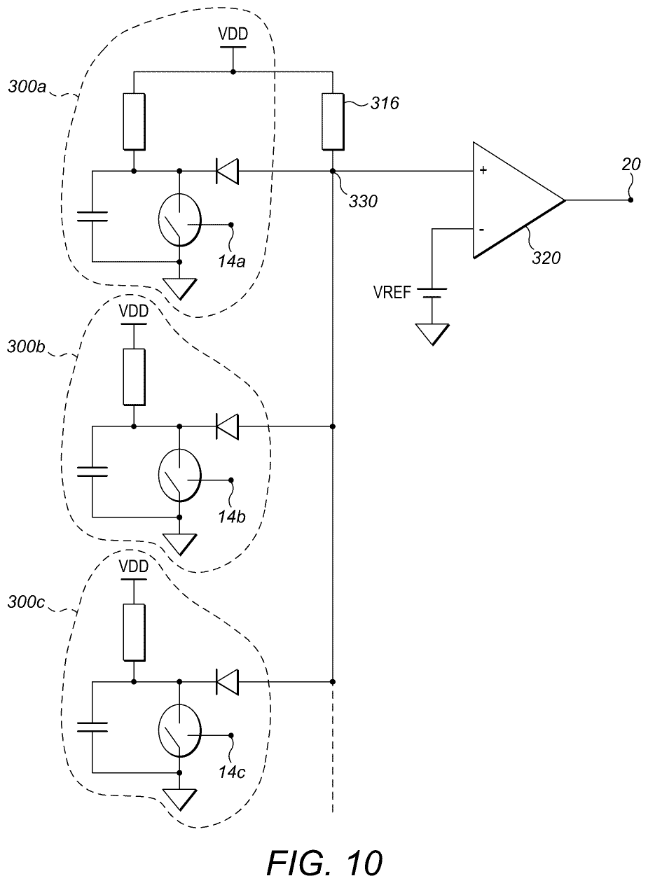

The output of the ramp generator 310 may be connected to control logic 320 comprising a comparator 322, to control the common node 20 to be in the first state or the second state depending on the output of the ramp generator 310. Nevertheless, as described in relation to FIG. 10, the output of the ramp generator 310 may be connected to a bus node, to which outputs from ramp generators associated with other gate drivers may be connected. In this case, the comparator 320 may be a common comparator that may be provided before input to a controller 60 for timing measurement, or as part of the controller 60.

Of course, the depicted ramp generator 310 is by way of example only, and other topologies of the ramp generator 310 are possible and would be readily implemented. For example, the ramp generator 310 may provide a decreasing voltage output. The output voltage of the ramp generator 310 may vary in a substantially linear manner, or may vary in non-linear manner. The ramp generator 310 simply needs to generate a monotonic and predictable varying output voltage.

A switch 324 is connected across the capacitor, which is controlled based on the state of the fault output node 14. Accordingly, as shown in the timing diagram of FIG. 9, when the fault output node 14 of the gate driver is in the fault state, the switch 324 closes. This discharges the capacitor 312, and as a result pulls the common node 20 to ground (as the voltage across the capacitor 312, therefore output by the ramp generator 310, no longer satisfies a voltage condition). That is, the voltage across the capacitor 312 falls below VREF, and therefore the comparator 322 outputs a low signal. Then, when the fault output node 14 of the gate driver is reset to the operating state, the switch 324 opens. As a result, the capacitor 322 will be charged by the voltage source through the first resistor 314 and the second resistor 316.

The time taken for the voltage across the capacitor 312 to reach VREF (e.g., satisfy the voltage condition), will be dependent on the resistances of the first resistor 314 and second resistor 316, and the capacitance of the capacitor 312. Thus, these values may be selected in order to achieve the desired predetermined time period of the individual timing arrangement 300.

FIG. 10 depicts a circuit diagram of a gate drive system according to an implementation of the implementation comprising timing arrangements 300a-c as depicted in FIG. 8.

As shown the ramp generator of each timing arrangement 300a-c shares a common second resistor 316. Furthermore, the output of each timing arrangement connects to a bus node 330. In turn, the bus node 330 is connected to a common comparator 320. The comparator 320 is configured to provide either a high or a low output to the common node 20. The output of the comparator 320 may either be directly connected to the common node 20, or may be connected to the gate of a switch of a switching arrangement to control the state of the common node 20. In other words, the comparator compares the voltage on the bus node 330 to a reference voltage VREF to generate a comparison result, and then sets the common node 20 to the first state or releases the common node 20 from the first state based on the comparison result.

In some implementations, the comparator 320 may be part of the controller 60. That is, the bus node 330 may connect to a comparator 320 as part of the controller 60 to measure the time elapsed from the trigger event. Nevertheless, the comparator 320 may also be separately provided, with an output of the comparator provided to the controller 60.

By way of brief explanation, if any of the fault output nodes 14a-c enters a fault state, the switch of the associated timing arrangement 300a-c will close. This will pull the bus node 330 to ground by virtue of creating a short circuit to ground, whilst only the respective capacitor associated with the timing arrangement 300a-c will be discharged. Accordingly, the voltage on the bus node 330 fails to meet the voltage condition VREF of the comparator 320, and the common node 20 will be pulled to the first state.

Then, when the switch of the timing arrangement 300a-c opens (after the fault output node 14a-c is reset to an operating state), the associated capacitor will recharge and the voltage on the bus node 330 will gradually increase. Once the voltage on the bus node 330 meets the voltage condition VREF of the comparator 320, the common node 20 will be released to the second state.

It is preferable that the second resistor 316 has a much greater resistance than any of the first resistors of the timing arrangements 300a-c. As a result, the charge time of each of the capacitors can be dominated by the respective first resistor.

Each of the capacitors of the timing arrangements 300a-c may have the same capacitance, whilst each of the first resistors of the timing arrangements 300a-c have a different resistance to set a rising time to the ramp generator according to the respective predetermined time period of the timing arrangement 300a-c. Alternatively, each of the first resistors of the timing arrangements 300a-c may have the same resistance, whilst each of the capacitors of the timing arrangements 300a-c have a different capacitance to set a rising time to the ramp generator according to the respective predetermined time period of the timing arrangement 300a-c. Of course, both the resistance and capacitance values of each of the timing arrangements 300a-c may vary, but this may be more expensive and complicated to implement (and therefore it may be preferable to only vary only one of the resistance or capacitance between each timing arrangement).

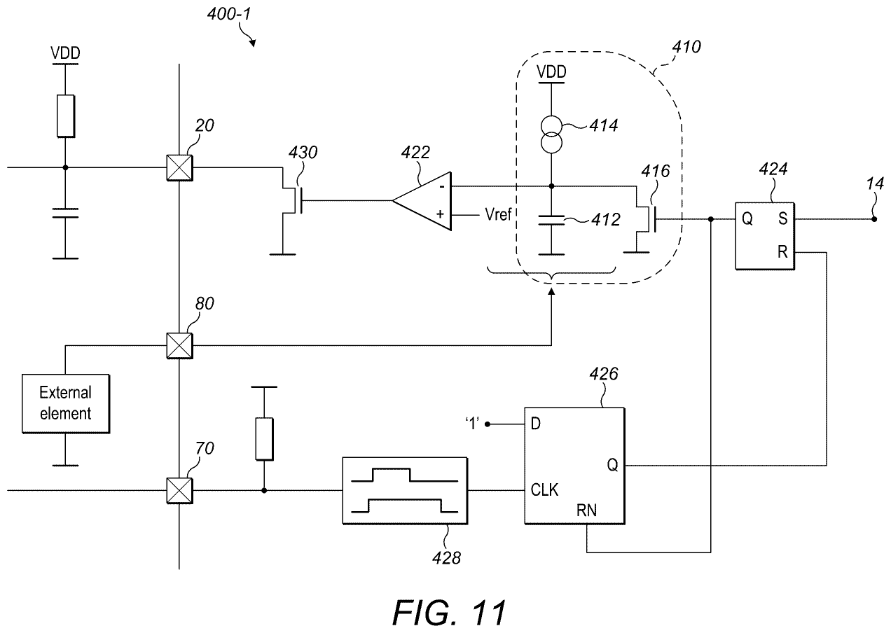

Moving onto FIG. 11, there is presented a circuit diagram of another example implementation of the timing arrangement 400 for a gate driver system. The timing arrangement 400 operates according to the trigger event being the resetting of a stored fault indicator associated with the associated gate driver (e.g., by SR-latch 424). That is, after the fault output node 14 of the respective gate driver 10 is set to a fault state, a fault indicator is stored. The trigger event occurs when the stored fault indicator is reset (e.g., to an operating indicator). If the fault output node remains in the fault state at the time that the reset occurs, a fault indicator continues to be stored and the trigger event does not begin.

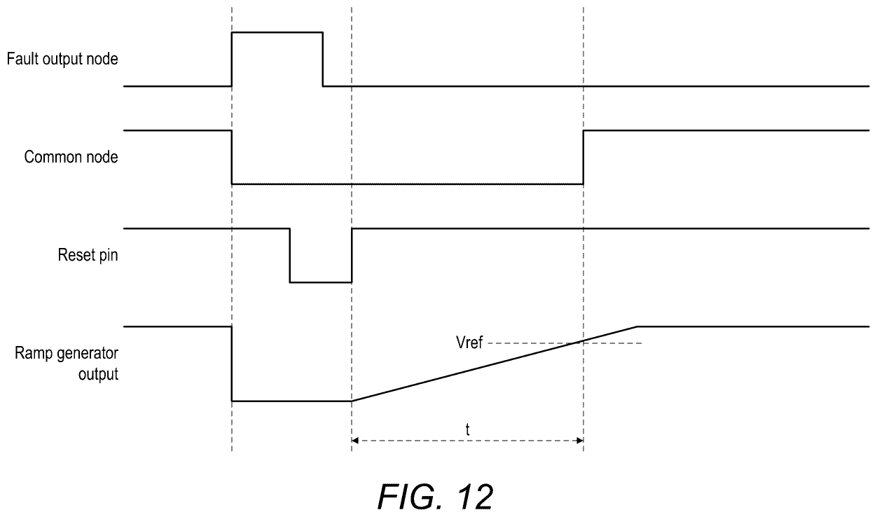

Accordingly, the timing arrangement 400 of FIG. 11 initially sets the common node 20 to the first state, waits for a reset signal resetting the fault indicator, delays for a predetermined time period, and then releases the common node 20 from the first state. The operation of the timing arrangement 400 of FIG. 11 is also explained with reference to the timing diagram of FIG. 12.

The timing arrangement 400 of FIG. 11 may be implemented in/within a gate driver 10 (similarly to the timing arrangement of FIG. 3). That is, the fault output node 14 of the gate driver 10 may be an internal node of the gate driver 10 (e.g., not an output pin), and many of the components of the timing arrangement 400 of FIG. 11 may be provided in the gate driver 10. Of course, each of these components may also be provided separately to the gate driver 10, with the fault output node 14 being an output pin of the gate driver.

During normal operation of the gate driver 10 (e.g., when the gate driver 10 has not detected a fault), an output switch of the timing arrangement 400 remains open, and therefore the output of the timing arrangement 400 does not pull the common node 20 to the first state.

When an internal fault signal on the fault output node 14 triggers the set of an SR-latch 424, a fault indictor is stored resulting in the output Q of the SR-latch 424 being set to high. The capacitor 412 of the ramp generator 410 will be discharged as the output Q of the SR-latch closes the switch 416 of the ramp generator 410. This results in the open drain switch 430 to be closed (as the voltage across the capacitor 412 no longer satisfies the voltage condition of the comparator 422), thus pulling the output of the timing arrangement 400 to a low state (in turn, pulling the common node 20 to a low state).

When the reset pin 70 is pulled to a low state a negative edge is produced at the clock input of the D flip flop 426. Once the reset pin 70 is pulled high again, a positive edge will be produced at the clock input of the D flip flop 426, clocking through a ‘1’ to the Q output, as the D input of the D-FF 426 is permanently connected to a ‘1’. Accordingly, a reset of the SR-latch 424 is prompted, removing the fault indicator, to an operating indicator, as long as the fault output node 14 is also in an operating state at the time.

As the SR-latch 424 is reset, the switch 416 will be opened. The reset of the SR-latch 424 will also reset the D flip flop 426.

Then, once the output voltage of the ramp generator 410 meets a voltage condition of the comparator 422 (e.g., once the output voltage exceeds a reference voltage value), the open drain switch 430 will be opened, thus releasing the output of the timing arrangement 400 from the low state.

In other words, the depicted timing arrangement 400 comprises a ramp generator 410 configured to generate a ramped output voltage responsive to the stored fault indicator being reset whilst the fault output node 14 of the respective gate driver 10 (a node internal to the gate driver 10 in this case) is in an operating state.

To this end, the ramp generator 410 comprises a switch 416 which, when closed, discharges the capacitor 412, and a current source 414 which, when the switch 416 is open, charges the capacitor 412. The switch 416 is controlled by internal control logic (e.g., the SR-latch 424, D flip-flop 426, negative edge delay 428) that causes the switch 416 to open when the gate driver 10 detects a fault, and causes the switch 416 to close responsive to a valid reset signal for the gate driver 10 on the reset pin 70.

The timing arrangement 400 further comprises output control logic (e.g., the comparator 422, and the open drain output switch 430) configured to set the common node 20 (e.g., the output pin of the gate drive 10) to the first state responsive to the ramped output voltage failing to meet a voltage condition (e.g., when the voltage across the capacitor is less than a threshold voltage VREF). The output control logic further releases the common node 20 from the first state responsive to the ramped output voltage meeting the voltage condition.

Of course, components of the ramp generator 410 may be chosen such that the output voltage of the ramp generator 410/the voltage across the capacitor 412 meets the voltage condition after a predetermined length of time (which varies between timing arrangements 400). Specifically, the capacitance of the capacitor 412 and/or the amperage of the current source 414 may be chosen to meet this aim. Alternatively, the voltage condition implemented by the comparator 422 of the control logic may be selected such that the ramp generator 410 meets the voltage condition after the predetermined length of time.

In the depicted implementation, the predetermined time period may be adjusted via an adjustment pin 80. Accordingly, this would enable a user to select the predetermined time period associated with each gate driver 10. Specifically, components may be connected to the adjustment pin 80 in order to select a predetermined time period.

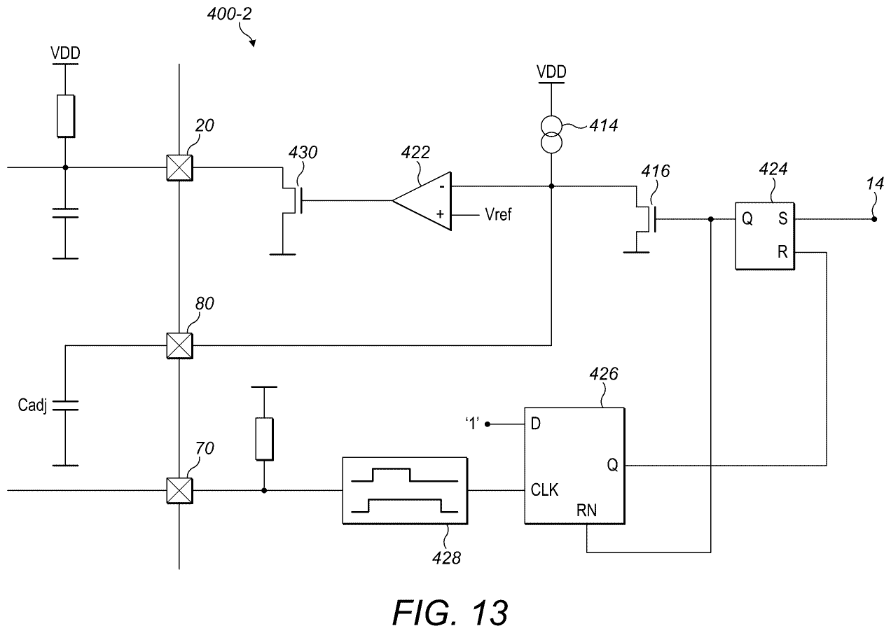

In a first implementation, as depicted in FIG. 13, the capacitor 412 of the ramp generator 410 may be provided by the adjustment pin 80. That is, rather than the capacitor 412 being an internal component, the adjustment pin 80 may be connected to the current source 414, and an external capacitor 412 may be connected between the adjustment pin 80 and ground.

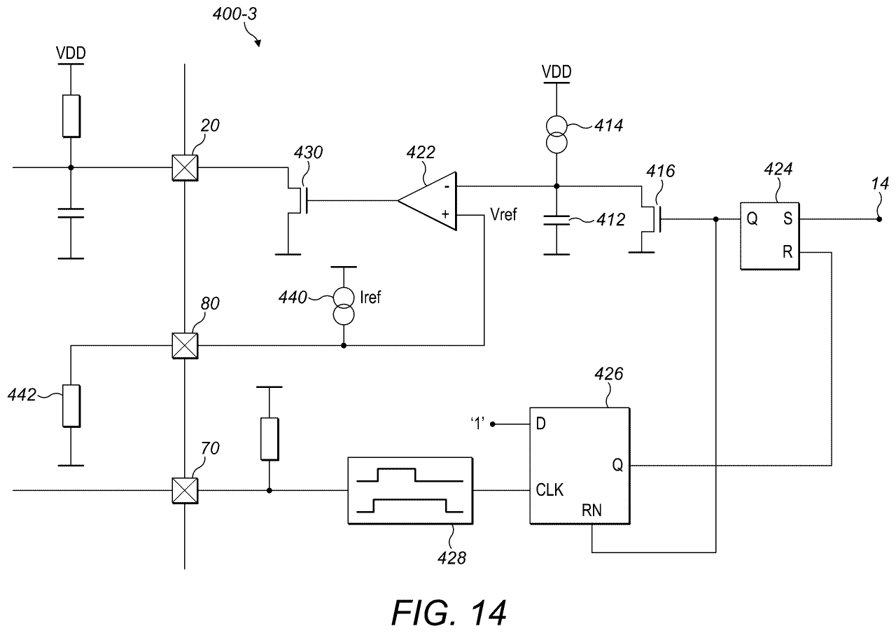

In another implementation, as depicted in FIG. 14, the reference voltage VREF of the comparator 422 may be provided by a reference current source 440 (which may be consistent between timing arrangements), and an external resistor 442 may be connected to the adjustment pin 80. Accordingly, the reference voltage VREF of the comparator 422 may be selected based on the resistance of the external resistor 442.

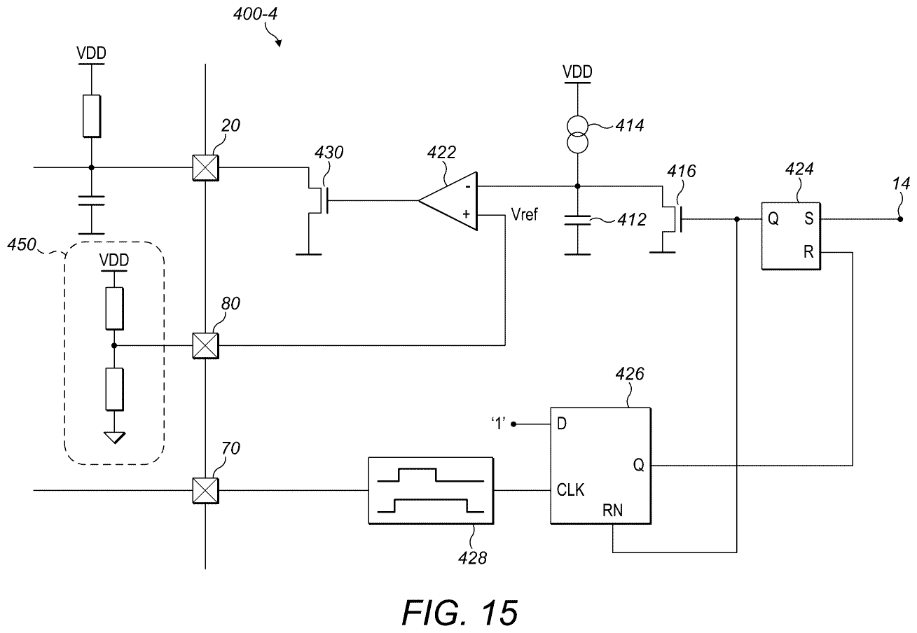

Alternatively, as depicted in FIG. 15, the reference voltage VREF of the comparator 422 may be provided by a voltage divider 450 adjusting a bus voltage VDD. Accordingly, a reference voltage VREF for the comparator 422 may be individually selected for each timing arrangement 400 by provision of a differently divided voltage divider 450 (e.g., having different resistance values). Alternatively, the voltage divider 450 may be replaced by a voltage source selected to provide an appropriate reference voltage VREF.

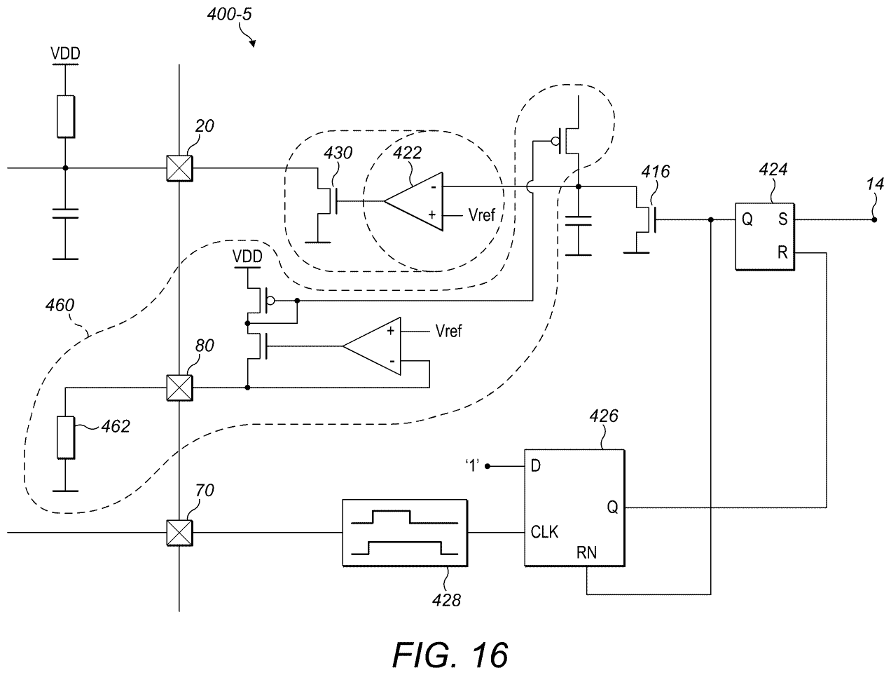

Finally, as depicted in FIG. 16, the current source 414 may be implemented as a current mirror 460, with the current provided by the current mirror 460 adjusted by an external resistor 462. In this case, the current provided by the current mirror 460 will depend upon the resistance of the external resistor 462, which may be selected to provide a different current for each of the timing arrangements.

Each of the timing arrangements 400a-400e may be implemented in the gate drive system 100 as described above, with different timing arrangements 40a-40c connected to different respective gate drivers 10a-10c being associated/configured to have different predetermined time periods.

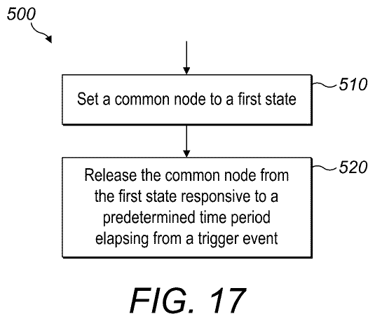

FIG. 17 presents a flow diagram of a method 500 for determining a location of a fault in a gate drive system according to an implementation of the implementation. The gate drive system is as described in reference to FIG. 1 and FIG. 2, comprising a plurality of gate drivers. Each gate driver has a fault output node (which may be a fault pin of the gate drive, or an internal node of the gate drive) switchable between a fault state indicating a detected fault by the respective gate driver and an operating state.

Specifically, step 510 involves setting a common node to a first state responsive to the fault output node of one of the gate drivers being set to the fault state. That is, if any of the fault output nodes are set to the fault state, the common node is set to a first state.

Then, in step 520, the common node is released from the first state responsive to a predetermined time period having elapsed from a trigger event. The amount of time (e.g., the predetermined time period) between the trigger event and the release of the common node depends on the gate driver that had reported the fault. In other words, the predetermined time period taken to release the common node is associated with the gate driver having the fault output node set to the fault state.

As each gate driver is associated with a different predetermined time period, the amount of time between the trigger event and the release of the common node may be measured to determine/identify the gate driver that has reported the fault.

In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The implementations may be implemented using hardware comprising several distinct elements. In a device claim enumerating several means, several of these means may be embodied by one and the same item of hardware. The mere fact that certain measures are recited in mutually different dependent claims does not indicate that a combination of these measures cannot be used to advantage. Furthermore, in the appended claims lists comprising “at least one of: A; B; and C” should be interpreted as (A and/or B) and/or C.

ASPECTS The following implementations are disclosed:

A gate drive system (100) comprising a plurality of gate drivers (10a, 10b, 10c), each gate driver having a fault output node (14a, 14b, 14c) switchable between a fault state indicating a detected fault by the respective gate driver and an operating state, the system comprising: a common node (20) that is switchable between a first state and a second state; a timing arrangement (40a, 40b, 40c) for each of the gate drivers, each timing arrangement connected to the fault output node of the respective gate driver and the common node, each timing arrangement configured to: set the common node to the first state responsive to the fault output node of the respective gate driver being set to the fault state; and release the common node from the first state responsive to a respective predetermined time period having elapsed from a trigger event, wherein the respective predetermined time period of each timing arrangement is different.

2. The system of implementation 1, further comprising a controller (60) connected to the common node (20) and configured to: measure a length of time between the trigger event and the common node switching to the second state; and identify the gate driver (10a, 10b, 10c) corresponding to the detected fault based on the measured length of time and the respective predetermined time period of each respective timing arrangement (40a, 40b, 40c).

3. The system of implementation 1 or 2, wherein the trigger event is either the common node (20) being set to the first state; or the fault output node (14a, 14b, 14c) of the respective gate driver (10a, 10b, 10c) being set to the operating state.

4. The system of implementation 1 or 2, wherein the trigger event is the common node (20) being set to the first state, and wherein each timing arrangement (200) comprises: a ramp generator (210) configured to generate a ramped output voltage responsive to the fault output node (14) of the respective gate driver (10) being set to the fault state; and
control logic (220) configured to: set the common node to the first state responsive to the fault output node of the respective gate driver being set to a fault state and the ramped output voltage failing to meet a first voltage condition; and release the common node from the first state responsive to the ramped output voltage meeting the first voltage condition.

5. The system of implementation 4, wherein the ramp generator (210) of each timing arrangement is configured to generate the respective ramped output voltage such that the respective ramped output voltage meets the first voltage condition once the respective predetermined time period of the timing arrangement (200) has elapsed from the trigger event, and wherein the first voltage condition of each timing arrangement is the same.

6. The system of implementation 4, wherein the first voltage condition of each timing arrangement (200) is selected such that the ramped output voltage generated by the respective ramp generator (210) meets the respective first voltage condition once the respective predetermined time period of the timing arrangement has elapsed from the trigger event.

7. The system of any of implementations 4-6, wherein the control logic (220) of each timing arrangement is further configured to set the common node (20) to the first state responsive to the ramped output voltage meeting a second common voltage condition and the first voltage condition.

8. The system of any of implementations 4-7, wherein the ramp generator (210) comprises:
a capacitor (212);
a current source (214); and
a switch (216) arranged to enable the current source to charge the capacitor responsive to the fault output node (14) of the respective gate driver (10) being set to the fault state.

9. The system of implementation 8, wherein a capacitance of the capacitor (212) and/or an amperage of the current source (214) of each ramp generator (210) is selected such that the respective ramped output voltage meets the first voltage condition once the respective predetermined time period of the timing arrangement has elapsed from the trigger event, and wherein the first voltage condition of each timing arrangement is the same.

10. The system of any of implementations 1-2, wherein the trigger event is the fault output node (14) of the respective gate driver (10) being set to the operating state, and wherein each timing arrangement (300, 400-1, 400-2, 400-3, 400-4, 400-5) comprises: a ramp generator (310, 410) configured to generate a ramped output voltage responsive to the fault output node (14) of the respective gate driver (10) being set to the operating state; and control logic (320, 420) configured to: set the common node (20) to the first state responsive to the fault output node of the respective gate driver being set to a fault state and the ramped output voltage failing to meet a voltage condition; and release the common node from the first state responsive to the ramped output voltage meeting a voltage condition.

11. The system of implementation 10, wherein the ramp generator (310, 410) of each timing arrangement (300, 400-1, 400-2, 400-3, 400-4, 400-5) is configured to generate the respective ramped output voltage such that the respective ramped output voltage meets the voltage condition once the respective predetermined time period of the timing arrangement has elapsed from the trigger event, and wherein the voltage condition of each timing arrangement is the same.

12. The system of implementation 10, wherein the voltage condition of each timing arrangement (300, 400-1, 400-2, 400-3, 400-4, 400-5) is selected such that the ramped output voltage generated by the respective ramp generator (310, 410) meets the respective voltage condition once the respective predetermined time period of the timing arrangement has elapsed from the trigger event.

13. The system of any of implementations 10-12, wherein the control logic (320, 420) of each timing arrangement comprises a comparator (322, 422) configured to: compare the ramped output voltage and a reference voltage (VREF), the reference voltage based on the voltage condition to generate a comparison result; set the common node (20) to the first state or release the common node from the first state based on the comparison result.

14. The system of any of implementations 1-13, further comprising a biasing arrangement (30) configured to bias the common node (20) to the second state, and wherein each timing arrangement (40a, 40b, 40c) further comprises a switching arrangement (50a, 50b, 50c) connected to the common node, the switching arrangement of each respective timing arrangement configured to: set the common node to the first state responsive to the fault output node of the respective gate driver being set to the fault state.

15. The system of any of implementations 1-14, wherein the first state is a low state, and the second state is a high state.

16. A method for determining a location of a fault in a gate drive system (100) comprising a plurality of gate drivers (10a, 10b, 10c), each gate driver having a fault output node (14a, 14b, 14c) switchable between a fault state indicating a detected fault by the respective gate driver and an operating state, the method comprising: setting (510) a common node (20) to a first state responsive to the fault output node of one of the gate drivers being set to the fault state; and releasing (520) the common node from the first state responsive to a respective predetermined time period having elapsed from a trigger event, the respective predetermined time period associated with the gate driver having the fault output node set to the fault state, and wherein the respective predetermined time period associated with each gate driver is different.

1. A gate drive system comprising:
a plurality of gate drivers, each gate driver having a fault output node switchable between a fault state indicating a detected fault by the respective gate driver and an operating state;
a common node that is switchable between a first state and a second state; and
a timing arrangement for each gate driver of the plurality of gate drivers, each timing arrangement connected to the fault output node of a respective gate driver and the common node, each timing arrangement configured to:
set the common node to the first state responsive to the fault output node of the respective gate driver being set to the fault state, and
release the common node from the first state responsive to a respective predetermined time period having elapsed from a trigger event, wherein the respective predetermined time period of each timing arrangement is different.

2. The system of claim 1, further comprising:
a controller connected to the common node and configured to:
measure a length of time between the trigger event and the common node switching to the second state, and
identify the gate driver corresponding to the detected fault based on the measured length of time and the respective predetermined time period of each respective timing arrangement.

3. The system of claim 1, wherein the trigger event is either the common node being set to the first state, or the fault output node of the respective gate driver being set to the operating state.

4. The system of claim 1, wherein the trigger event is the common node being set to the first state, and wherein each timing arrangement comprises:
a ramp generator configured to generate a ramped output voltage responsive to the fault output node of the respective gate driver being set to the fault state; and
control logic configured to:
set the common node to the first state responsive to the fault output node of the respective gate driver being set to a fault state and the ramped output voltage failing to meet a first voltage condition, and
release the common node from the first state responsive to the ramped output voltage satisfying the first voltage condition.

5. The system of claim 4, wherein the ramp generator of each timing arrangement is configured to generate the respective ramped output voltage such that the respective ramped output voltage satisfies the first voltage condition once the respective predetermined time period of the timing arrangement has elapsed from the trigger event, and wherein the first voltage condition of each timing arrangement is the same condition.

6. The system of claim 4, wherein the first voltage condition of each timing arrangement is selected such that the ramped output voltage generated by the respective ramp generator satisfies the respective first voltage condition once the respective predetermined time period of the timing arrangement has elapsed from the trigger event.

7. The system of claim 4, wherein the control logic of each timing arrangement is further configured to set the common node to the first state responsive to the ramped output voltage satisfying a second common voltage condition and the first voltage condition.

8. The system of claim 4, wherein the ramp generator comprises:
a capacitor;
a current source; and
a switch arranged to enable the current source to charge the capacitor responsive to the fault output node of the respective gate driver being set to the fault state.

9. The system of claim 8, wherein a capacitance of the capacitor and/or an amperage of the current source of each ramp generator is selected such that the respective ramped output voltage satisfies the first voltage condition once the respective predetermined time period of the timing arrangement has elapsed from the trigger event, and wherein the first voltage condition of each timing arrangement is the same.

10. The system of claim 1, wherein the trigger event is the fault output node of the respective gate driver being set to the operating state, and wherein each timing arrangement comprises:
a ramp generator configured to generate a ramped output voltage responsive to the fault output node of the respective gate driver being set to the operating state; and
control logic configured to:
set the common node to the first state responsive to the fault output node of the respective gate driver being set to a fault state and the ramped output voltage failing to meet a voltage condition, and
release the common node from the first state responsive to the ramped output voltage satisfying a voltage condition.

11. The system of claim 10, wherein the ramp generator of each timing arrangement is configured to generate the respective ramped output voltage such that the respective ramped output voltage satisfies the voltage condition once the respective predetermined time period of the timing arrangement has elapsed from the trigger event, and wherein the voltage condition of each timing arrangement is the same.

12. The system of claim 10, wherein the voltage condition of each timing arrangement is selected such that the ramped output voltage generated by the respective ramp generator satisfies the respective voltage condition once the respective predetermined time period of the timing arrangement has elapsed from the trigger event.

13. The system of claim 10, wherein the control logic of each timing arrangement comprises a comparator configured to:
compare the ramped output voltage and a reference voltage (VREF) to generate a comparison result, the reference voltage based on the voltage condition, and
set the common node to the first state or release the common node from the first state based on the comparison result.

14. The system of claim 1, further comprising:
a biasing arrangement configured to bias the common node to the second state, and wherein each timing arrangement further comprises a switching arrangement connected to the common node, the switching arrangement of each respective timing arrangement configured to:
set the common node to the first state responsive to the fault output node of the respective gate driver being set to the fault state.

15. The system of claim 1, wherein the first state is a low state, and the second state is a high state.

16. A method for determining a location of a fault in a gate drive system comprising a plurality of gate drivers, each gate driver having a fault output node switchable between a fault state indicating a detected fault by the respective gate driver and an operating state, the method comprising:
setting a common node to a first state responsive to the fault output node of one of the gate drivers being set to the fault state; and
releasing the common node from the first state responsive to a respective predetermined time period having elapsed from a trigger event, the respective predetermined time period associated with the gate driver having the fault output node set to the fault state,
wherein the respective predetermined time period associated with each gate driver is different.
